(19) United States
(12) Patent Application Publication
(10) Pub. No.: US 2008/0164527 A1
(43) Pub. Date: Jul. 10, 2008

(54) SEMICONDUCTOR DEVICE AND METHOD OF MANUFACTURING THE SAME

(76) Inventors: Takashi Kataoka, Fukuoka-ken (JP); Atsuko Yamashita, Kanagawa-ken (JP); Yoshiharu Kouji, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/955,998

(22) Filed: Dec. 13, 2007

(30) Foreign Application Priority Data
Dec. 15, 2006 (JP) 2006-338275

(51) Int. Cl. H01L 23/62; H01L 21/3205

(52) U.S. Cl. 257/356; 438/591; 257/E23.001; 257/E21.294

(57) ABSTRACT

The semiconductor comprises a channel layer including GaN, a barrier layer formed by laminating a first layer including Al_{X}Ga_{1-X}N (0.05≦X≦0.25) and a second layer including Al_{Y}Ga_{1-Y}N (0.20≦Y≦0.28, X<Y), source and drain electrodes provided spaced apart from each other on the barrier layer, and a gate electrode provided on the bottom of a ditch extending between the source and drain electrodes and formed with a depth starting from the top surface of the barrier layer reaching the first layer adjacent to the channel layer.

### CROSS-REFERENCE TO RELATED APPLICATIONS

This application is based upon and claims the benefit of priority from the prior Japanese Patent Application No. 2006-338275, filed on Dec. 15, 2006; the entire contents of which are incorporated herein by reference.

### BACKGROUND OF THE INVENTION

1. Field of the Invention

This invention relates to a semiconductor device, and more particularly to a field effect transistor having a group-III nitride semiconductor

2. Background Art

A group-III nitride semiconductor including gallium nitride (hereinafter, abbreviated as GaN) is counted on as the material of a semiconductor device for high power, high frequency and high temperature, and actively researched and developed because it has a wider bandgap and higher dielectric breakdown strength than silicon (Si) and gallium arsenide (GaAs). In particular, a field effect transistor using a GaN(gallium nitride)/AlGaN(aluminum gallium nitride) hetero structure (hereinafter, the transistor being abbreviated as GaN/AlGaN-HFET) has a simple element structure, and can be expected to exhibit good element properties.

Particularly, in the GaN/AlGaN-HFET for a high-breakdown-voltage switching device, the concentration and mobility of a two-dimensional carrier gas formed at the interface of the GaN/AlGaN hetero structure can be expected to be increased by increasing the Al (aluminum) composition ratio of AlGaN which serves as a barrier layer (carrier supply layer) to suppress the power consumption of the element. On the other hand, in a normally-on type element, a high current flows through the element at the moment when the power supply of a circuit is turned on. Such a high current may sometimes break down the element. Accordingly, a normally-off type element has to be employed to prevent such a breakdown, because hardly any current flows through the type of element with a 0-V gate voltage.

For example, JP-A 2005-277047 (Kokai) discloses an element structure in which the concentration and mobility of the two-dimensional carrier gas formed in the channel layer is increased by providing a barrier layer (carrier supply layer) having a high Al composition ratio of 0.5 or more on the channel layer including GaN.

To suppress a leak current between source and drain electrodes under the gate-off condition, a recess gate type structure, for example, has to be employed in the above-described element structure. Nevertheless, even such a structure is quite unlikely to bring about normally-off type characteristics, because of the effect of a barrier layer having a high Al(aluminum) composition ratio of 0.5 or more.

### SUMMARY OF THE INVENTION

According to an aspect of the invention, provided is a semiconductor device including: a channel layer including GaN; a barrier layer formed by laminating a first layer formed on the channel layer and including Al_{X}Ga_{1-X}N (0.05≦X≦0.25) and a second layer including Al_{Y}Ga_{1-Y}N (0.20≦Y≦0.28, X<Y); source and drain electrodes provided spaced apart from each other on the barrier layer; and a gate electrode provided on the bottom of a ditch extending between the source and drain electrodes and formed with a depth starting from the top surface of the barrier layer reaching the first layer adjacent to the channel layer.

According to another aspect of the invention, there is provided a method of manufacturing a semiconductor device including: providing a channel layer including GaN; forming barrier layer on the channel layer by laminating a first layer including Al_{X}Ga_{1-X}N (0.05≦X≦0.25) and a second layer including Al_{Y}Ga_{1-Y}N (0.20≦Y≦0.28, X<Y) in order; forming a ditch in the barrier layer with a depth starting from the top surface of the barrier layer reaching the first layer adjacent to the channel layer; forming a gate electrode in the ditch in the barrier layer.

### BRIEF DESCRIPTION OF THE DRAWINGS

FIG. 1 shows a diagrammatic drawing exemplifying the cross-sectional structure of a GaN/AlGaN-HFET related to the first embodiment of the present invention.

FIG. 2 shows a cross-sectional view showing the main section of a production process of the GaN/AlGaN-HFET of the FIG. 1.

FIG. 3 shows a cross-sectional view showing the main section of a production process of the GaN/AlGaN-HFET of the FIG. 1.

FIG. 4 shows a diagrammatic drawing exemplifying the cross-sectional structure of the GaN/AlGaN-HFET related to the second embodiment of the present invention.

FIG. 5 shows a cross-sectional view showing the main section of a production process of the GaN/AlGaN-HFET of the FIG. 4.

FIG. 6 shows a cross-sectional view showing the main section of a production process of the GaN/AlGaN-HFET of the FIG. 4.

FIG. 7 shows a diagrammatic drawing exemplifying the cross-sectional structure of the GaN/AlGaN-HFET in the case where an MIS type gate structure is employed in the first embodiment of the present invention.

### DETAILED DESCRIPTION OF THE INVENTION

Referring to the drawings, the embodiments of the present invention are described below.

### First Embodiment

FIG. 1 is a diagrammatic drawing exemplifying the cross-sectional structure of a field effect transistor using a GaN(gallium nitride)/AlGaN(aluminum gallium nitride) hetero structure (hereinafter, the transistor being abbreviated as GaN/AlGaN-HFET) related to the first embodiment of the present invention.

As shown in FIG. 1, a buffer layer 12 such as an AlN(aluminum nitride) layer is mounted on a substrate 10. Al₂O₃ (Sapphire), SiC(silicon carbide), and Si(silicon) are used as the substrate 10. A channel layer 14 including a GaN (gallium nitride) layer is provided on the buffer layer 12. The buffer layer 12 is used as the nucleation layer of the channel layer 14 including a GaN layer. A barrier layer 20 formed by alternately laminating the first layers 16 including Al_{X}Ga_{1-X}N (aluminum gallium nitride, 0.05≦X≦0.25, for example, X=0.2) and the second layers 18 including Al_{Y}Ga_{1-Y}N (aluminum gallium nitride, 0.20≦Y≦0.28, X<Y, for example, Y=0.25) is formed on the channel layer 14. The film thickness of the first layer 16 and the second layer 18 is, for example, 5 nm and 2 nm, respectively.

A hetero semiconductor junction is formed between the channel layer 14 and the first layer 16 including Al_{X}Ga_{1-X}N (0.05≦X≦0.25). A two-dimensional carrier gas is induced on the side of the channel layer of the hetero semiconductor junction, and functions as a conduction channel.

The Al(aluminum) composition ratio of the above-described first layer may be within a range of 0.05 or more to 0.25 or less. When the Al composition ratio X is 0.05 or more, the hetero semiconductor junction can be formed between the first layer 16 and the channel layer 14. On the other hand, when the Al composition ratio X is 0.25 or less, a leak current between the source and drain electrodes can be suppressed to a low level under the gate-off condition. The Al composition ratio Y of the second layer may be in a relation of X<Y relative to the above-described Al composition ratio X, and within a range of 0.20 or more to 0.28 or less. When the Al composition ratio Y is 0.20 or more, the concentration and mobility of the two-dimensional carrier gas can sufficiently be increased. On the other hand, when the Al composition ratio Y is 0.28 or less, a crack formation due to the lattice mismatch between the channel layer 14 and the barrier layer 20 can sufficiently be inhibited.

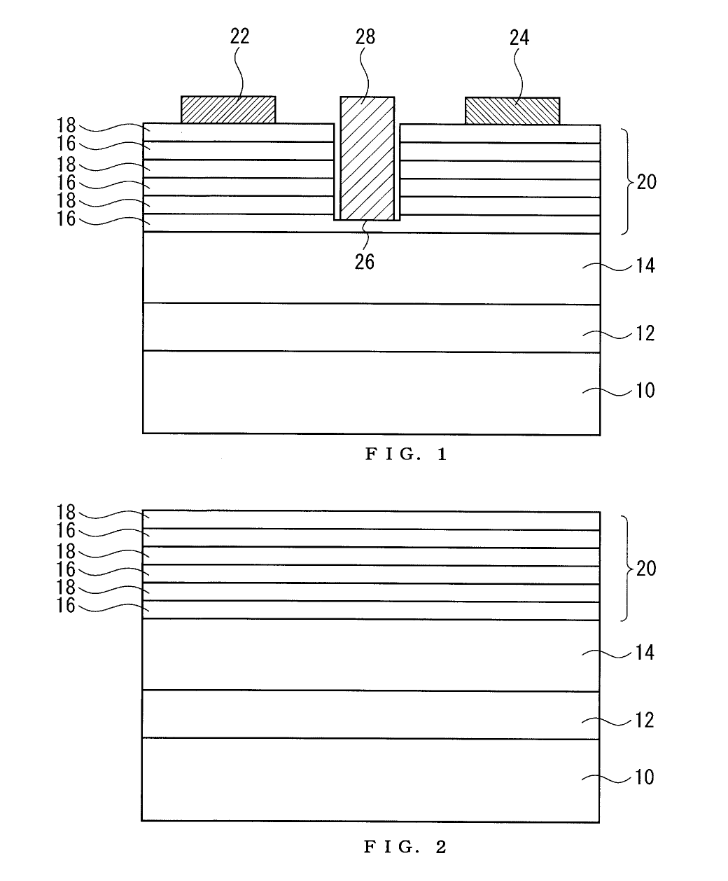

The above-described barrier layer 20 may be formed by repeating a cycle of laminating a film comprised of the first layer 16 and the second layer 18, for example, three to ten times, if the Al composition ratio is within the above range. In FIG. 2, the number of the repeated cycles of the barrier layer 20 is three. When the number of the repeated cycles of the barrier layer 20 is three or more, the concentration and mobility of the two-dimensional carrier gas can sufficiently be increased. On the other hand, when the number of repeated cycles of the barrier layer 20 is ten or less, a crack formation due to the lattice mismatch between the channel layer 14 and the barrier layer 20 can sufficiently be inhibited. The accumulated layer thickness of the barrier layer 20 is preferably 20 nm or more and 70 nm or less to inhibit the above-described crack formation, and to increase the concentration and mobility of the two-dimensional carrier gas.

A source electrode 22 and a drain electrode 24 are provided spaced apart from each other on the barrier layer 20. A ditch 26 extending from the top surface of the barrier layer 20 to the first layer 16 (adjacent to the channel layer 14) is provided between the source electrode 22 and the drain electrode 24. A gate electrode 28 is provided on the bottom of the ditch 26 (This is a so-called recess gate structure).

In providing the ditch 26 for a gate, the second layer 18 having a higher Al composition ratio than the first layer 16 is intentionally removed from a gate forming region. In the present embodiment, the thickness and Al composition ratio of the barrier layer 20 located under the gate electrode are intentionally reduced by providing the recess gate structure with the first layer 16 having a lower Al composition ratio than the second layer 18. By this reduction, the two-dimensional carrier gas of the hetero semiconductor junction corresponding to a gate region can be drained under the gate-off condition. As a result, normally-off type characteristics can be obtained while suppressing the leak current between the source and drain electrodes to a low level under the gate-off condition. On the other hand, in a region other than the gate region, Al_{Y}Ga_{1-Y}N (0.20≦Y≦0.28, X<Y, for example, Y=0.25) having the higher Al composition ratio is provided to the second layer 18 in the barrier layer 20. Accordingly, at the hetero semiconductor junction interface corresponding to a region other than the gate region, the concentration and mobility of the two-dimensional carrier gas induced therein can be increased.

### Production Method of the First Embodiment

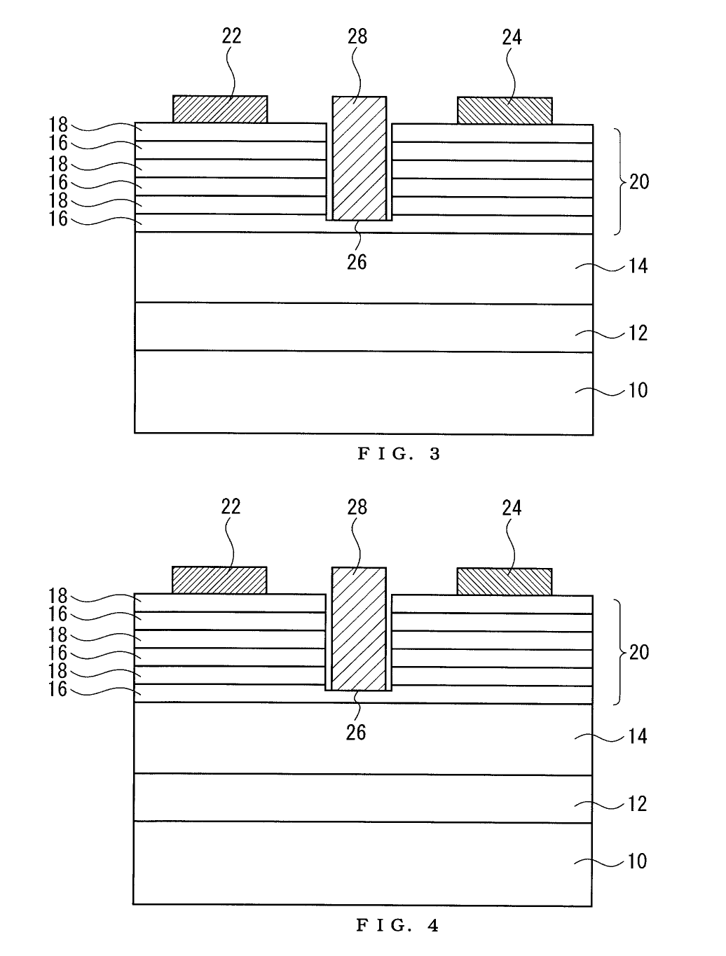

FIGS. 2 and 3 are cross-sectional views showing the main sections of production processes of GaN/AlGaN-HFET related to the present embodiment.

As shown in FIG. 2, a buffer layer 12 such as an AlN layer is formed on the substrate 10 by, for example, an MOVPE(metal organic vapor phase epitaxy) method. As the substrate 10, Sapphire, SiC, and Si are used. The channel layer 14 including a GaN layer is formed on the buffer layer 12 again by the MOVPE method. Here, the buffer layer 12 is used as the nucleation layer of the channel layer 14 including a GaN layer. The barrier layer 20 formed by laminating the first layer 16 including Al_{X}Ga_{1-X}N (0.05≦X≦0.25, for example, X=˜0.2) and the second layer 18 including Al_{Y}Ga_{1-Y}N (0.20≦Y≦0.28, X<Y, for example, Y=0.25) is formed on the channel layer 14 again by the MOVPE method. The thickness of the first layer 16 and the second layer 18 is, for example, 5 nm and 2 nm, respectively. Here, a sputter method and an MBE (molecular beam epitaxy) method can also be used in addition to the MOVPE method as a method for forming the above each layer.

The Al composition ratio of the above-described first layer may be within a range of 0.05 or more to 0.25 or less. When the Al composition ratio X is 0.05 or more, a hetero semiconductor junction can be formed between the first layer 16 and the channel layer 14. On the other hand, when the Al composition ratio X is 0.25 or less, the leak current between the source and drain electrodes under the gate-off condition can be suppressed to a low level. The Al composition ratio Y of the second layer is in relation of X<Y, and within a range of 0.20 or more to 0.28 or less. When the Al composition ratio Y is 0.20 or more, the concentration and mobility of the two-dimensional carrier gas can sufficiently be increased. On the other hand, when the Al composition ratio Y is 0.28 or less, the crack formation due to the lattice mismatch between the channel layer 14 and the barrier layer 20 can sufficiently be inhibited.

The above-described barrier layer 20 may be formed by repeating a cycle of laminating a film comprised of the first layer 16 and the second layer 18, for example, three to ten times, if the Al composition ratio is within the above range. In FIG. 2, the number of the repeated cycles of the barrier layer 20 is three. When the number of the repeated cycles of the barrier layer 20 is three or more, the concentration and mobility of the two-dimensional carrier gas can sufficiently be increased. On the other hand, when the number of repeated cycles of the barrier layer 20 is ten or less, a crack formation due to the lattice mismatch between the channel layer 14 and the barrier layer 20 can sufficiently be inhibited. The accumulated layer thickness of the barrier layer 20 is preferably 20 nm or more and 70 nm or less to inhibit the above-described crack formation, and to increase the concentration and mobility of the two-dimensional carrier gas. As shown in FIG. 3, the source electrode 22 and the drain electrode 24 are formed spaced apart from each other on the barrier layer 20 by, for example, a lift-off method. Here, the electrodes are made of, for example, a laminated film such as a Ti (titanium)/Al (aluminum) laminated film. The ditch 26 is provided between the source electrode 22 and the drain electrode 24 on the barrier layer 20 by an RIE(reactive ion etching) method using, for example, an unillustrated nitride film as a mask. At this time, etching is carried out so that the first layer 16 including an Al_{X}Ga_{1-X}N layer is exposed at the bottom of the ditch 26.

Al composition ratio differs between the first layer 16 and the second layer 18 of the barrier layer 20, and consequently, so does Ga(gallium) composition ratio. Accordingly, by monitoring the luminescence intensity of Ga, the depth of the ditch 26 can be accurately controlled to be a desired depth in forming the ditch 26 by the RIE method and the like. The method for monitoring the luminescence intensity of Ga allows the depth of the ditch 26 to be monitored in real time, and therefore makes it possible to control the depth of the ditch 26 with higher accuracy than by a conventional method in which the depth of the ditch 26 is controlled by the etching time.

Thereafter, a recess type gate electrode 28 is formed on the bottom of the ditch 26 by the lift-off method and the like. Here, the electrodes are made of, for example, a laminated film such as an Ni(nickel)/Au(aurum) laminated film.

The thickness and Al composition ratio of the part of the barrier layer 20 located under the gate electrode 28 can intentionally be reduced by exposing the first layer including an Al_{X}Ga_{1-X}N layer at the bottom of the ditch 26 as described above. By this reduction, the two-dimensional carrier gas of the hetero semiconductor junction corresponding to the gate region can be drained under the gate-off condition. As a result, normally-off type characteristics can be obtained while suppressing the leak current between the source and drain electrodes to a low level under the gate-off condition. On the other hand, in the region other than the gate region, Al_{Y}Ga_{1-Y}N (0.20≦Y≦0.28, X<Y, for example, Y=0.25) having the higher Al composition ratio is provided to the second layer 18 in the barrier layer 20. Accordingly, on the hetero semiconductor junction corresponding to the region other than the gate region, the concentration and mobility of the two-dimensional carrier gas induced therein can be increased.

### Second Embodiment

FIG. 4 is a diagrammatic drawing exemplifying the cross-sectional structure of the GaN/AlGaN-HFET related to the second embodiment of the present invention.

The difference of the present embodiment from the first embodiment is that the Al composition ratio of Al_{X}Ga_{1-X}N (0.05≦X≦0.25, for example, X=0.2) included in the first layer 16 in the barrier layer 20 is increased in the direction from the side of the channel layer 14 toward the side of the source electrode 22 and the drain electrode 24. In each figure of the present embodiment, the same number and the same symbol are given to the same part as the parts shown in FIGS. 1 to 3 used to describe the semiconductor device and method for producing the same in the first embodiment.

### Element Structure of the Second Embodiment

A description of the process in which the channel layer 14 is provided on the buffer layer 12 in the element structure is the same as in the first embodiment. Accordingly, the description is omitted.

As shown in FIG. 4, the barrier layer 20 formed by laminating the first layer 16 including Al_{X}Ga_{1-X}N (0.05≦X≦0.25, for example, X=0.05, 0.2 from the channel layer 14) and the second layer 18 including Al_{Y}Ga_{1-Y}N (0.20≦Y≦0.28, X<Y, for example, Y=0.25) is formed on the channel layer 14. The thickness of the first layer 16 and the second layer 18 is, for example, 5 nm and 2 nm, respectively.

A hetero semiconductor junction is formed between the channel layer 14 and the first layer 16 including Al_{X}Ga_{1-X}N (0.05≦X≦0.25). A two-dimensional carrier layer is induced on the side of the channel layer 14 of the hetero semiconductor junction, and functions as a channel layer.

The Al composition ratio of the above-described first layer may be within a range of 0.05 or more to 0.25 or less. When the Al composition ratio X is 0.05 or more, a hetero semiconductor junction can be formed between the first layer 16 and the channel layer 14. On the other hand, when the Al composition ratio X is 0.25 or less, the leak current between the source and drain electrodes under the gate-off condition can be suppressed to a low level. The Al composition ratio Y of the second layer is in relation of X<Y, and may be within a range of 0.20 or more to 0.28 or less. When the Al composition ratio Y is 0.20 or more, the concentration and mobility of the two-dimensional carrier gas can sufficiently be increased. On the other hand, when the Al composition ratio Y is 0.28 or less, the crack formation due to the lattice mismatch between the channel layer 14 and the barrier layer 20 can sufficiently be inhibited.

The above-described barrier layer 20 may be formed by further repeating a cycle of laminating a film comprised of the first layer 16 and the second layer 18, on a film formed by laminating the first layer 16 and the second layer 18 so that the total number of the repeated cycles can be, for example, three to ten, if the Al composition ratio is within the above range. In FIG. 4, the number of the repeated cycles of the barrier layer 20 is three. When the number of the repeated cycles of the barrier layer 20 is three or more, the concentration and mobility of the two-dimensional carrier gas can sufficiently be increased. On the other hand, when the number of pitches of the barrier layer 20 is ten or less, a crack formation due to the lattice mismatch between the channel layer 14 and the barrier layer 20 can sufficiently be inhibited. The accumulated layer thickness of the barrier layer 20 is desirably 20 nm or more and 70 nm or less to inhibit the above-described crack formation, and to increase the concentration and mobility of the two-dimensional carrier gas.

The source electrode 22 and the drain electrode 24 are provided spaced apart from each other on the barrier layer 20. The ditch 26 extending from the top surface of the barrier layer 20 to the first layer 16 is provided between the source electrode 22 and the drain electrode 24. The gate electrode 28 is provided on the bottom of the ditch 26 (This is a so-called recess gate structure).

In providing the ditch 26 for a gate, the second layer 18 having a higher Al composition ratio than the first layer 16 is intentionally removed from a gate forming region. In the present embodiment, the thickness and Al composition ratio of the barrier layer 20 located under the gate electrode can intentionally be reduced by providing the recess gate structure with the first layer 16 having a lower Al composition ratio than the second layer 18. By this reduction, the two-dimensional carrier gas of the hetero semiconductor junction corresponding to a gate region can be drained under the gate-off condition. As a result, normally-off type characteristics can be obtained while suppressing the leak current between the source and drain electrodes to a low level under the gate-off condition. On the other hand, in a region other than the gate region, Al_{Y}Ga_{1-Y}N (0.20≦Y≦0.28, X<Y, for example, Y=0.25) having the higher Al composition ratio is provided to the second layer 18 in the barrier layer 20. Accordingly, at the hetero semiconductor junction interface corresponding to a region other than the gate region, the concentration and mobility of the two-dimensional carrier gas induced therein can be increased.

### Production Method of the Second Embodiment

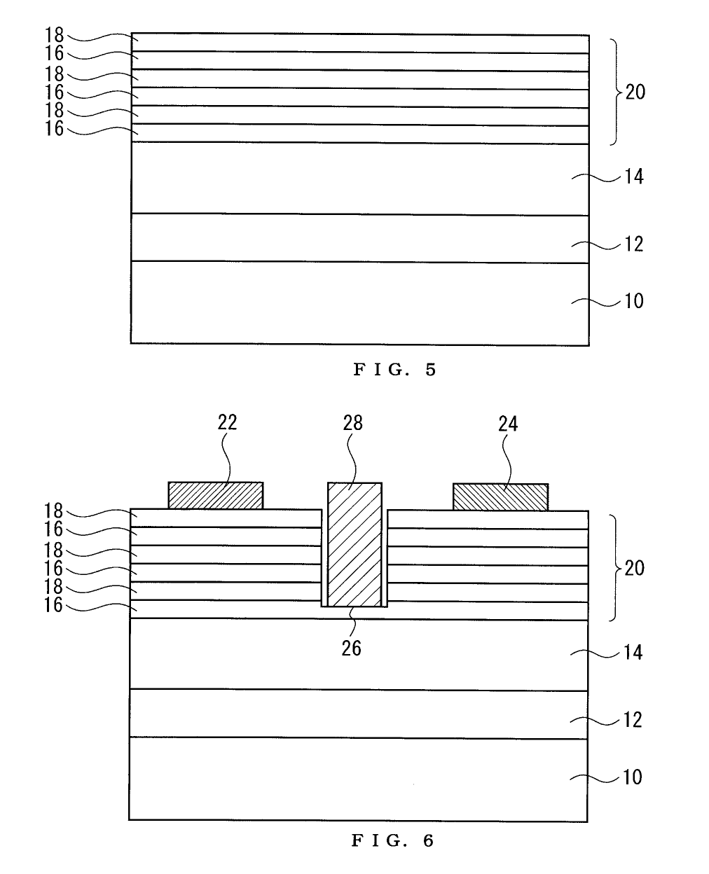

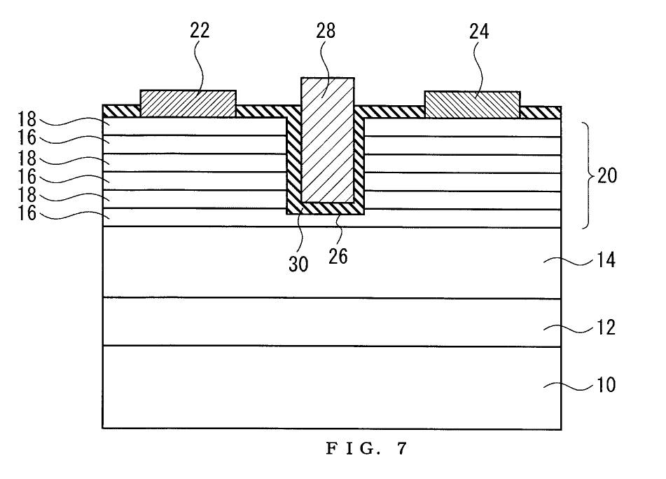

FIGS. 5 and 6 are cross-sectional views showing production processes of GaN/AlGaN-HFET related to the present embodiment. A description of the process in which the channel layer 14 is formed on the buffer layer 12 in the production method is the same as in the first embodiment. Accordingly, the description is omitted.

As shown in FIG. 5, the barrier layer 20 formed by laminating the first layer 16 including Al_{X}Ga_{1-X}N (0.05≦X≦0.25, for example, X=0.05, 0.2 from the channel layer 14) and the second layer 18 including Al_{Y}Ga_{1-Y}N (0.20≦Y≦0.28, X<Y, for example, Y=0.25) is formed on the channel layer 14 by, for example, an MOVPE method. The thickness of the first layer 16 and the second layer 18 is, for example, 5 nm and 2 nm, respectively. Here a sputter method, and an MBE method can also be used in addition to the MOVPE method as a method for forming the above each layer.

The Al composition ratio of the above-described first layer may be within a range of 0.05 or more to 0.25 or less. When the Al composition ratio X is 0.05 or more, a hetero semiconductor junction can be formed between the first layer 16 and the channel layer 14. On the other hand, when the Al composition ratio X is 0.25 or less, the leak current between the source and drain electrodes under the gate-off condition can be suppressed to a low level. The Al composition ratio Y of the second layer is in relation of X<Y, and within a range of 0.20 or more to 0.28 or less. When the Al composition ratio Y is 0.20 or more, the concentration and mobility of the two-dimensional carrier gas can sufficiently be increased. On the other hand, when the Al composition ratio Y is 0.28 or less, the crack formation due to the lattice mismatch between the channel layer 14 and the barrier layer 20 can sufficiently be inhibited.

The barrier layer 20 may be formed by further repeating a cycle of laminating, again by the MOVPE method, a film comprised of the first layer 16 and the second layer 18, on a film formed by laminating the first layer 16 and the second layer 18 so that the total number of the repeated cycles can be, for example, three to ten, if the Al composition ratio is within the above range. When the number of the repeated cycles of the barrier layer 20 is three or more, the concentration and mobility of the two-dimensional carrier gas can sufficiently be increased. On the other hand, if the number of pitches of the barrier layer 20 is ten or less, a crack formation due to the lattice mismatch between the channel layer 14 and the barrier layer 20 can sufficiently be inhibited. The accumulated layer thickness of the barrier layer 20 is desirably 20 nm or more and 70 nm or less to inhibit the above-described crack formation, and to increase the concentration and mobility of the two-dimensional carrier gas.

Then, as shown in FIG. 6, the source electrode 22 and the drain electrode 24 are formed spaced apart from each other on the barrier layer 20 by, for example, a lift-off method. Here, the electrodes are made of, for example, a laminated film such as a Ti/Al laminated film. The ditch 26 is provided between the source electrode 22 and the drain electrode 24 on the barrier layer 20 by an RIE method using, for example, an unillustrated nitride film as a mask. At this time, etching is carried out so that the first layer 16 including an Al_{X}Ga_{1-X}N layer is exposed at the bottom of the ditch 26.

Al composition ratio differs between the first layer 16 and the second layer 18 of the barrier layer 20, and consequently, so does Ga composition ratio. Accordingly, by monitoring the luminescence intensity of Ga, the depth of the ditch 26 can be accurately controlled to be a desired depth in forming the ditch 26 by the RIE method and the like. The method for monitoring the luminescence intensity of Ga allows the depth of the ditch 26 to be monitored in real time, and therefore makes it possible to control the depth of the ditch 26 with higher accuracy than by a conventional method in which the depth of the ditch 26 is controlled by the etching time.

Thereafter, a recess type gate electrode 28 is formed on the bottom of the ditch 26 by the lift-off method and the like. Here, the electrodes are made of, for example, a laminated film such as an Ni/Au laminated film.

The thickness and Al composition ratio of the part of the barrier layer 20 located under the gate electrode 28 can intentionally be reduced by exposing the first layer including an Al_{X}Ga_{1-X}N layer at the bottom of the ditch 26 as described above. By this reduction, the two-dimensional carrier gas of the hetero semiconductor junction corresponding to the gate region can be drained under the gate-off condition. As a result, normally-off type characteristics can be obtained while suppressing the leak current between the source and drain electrodes to a low level under the gate-off condition. On the other hand, in the region other than the gate region, Al_{Y}Ga_{1-Y}N (0.20≦Y≦0.28, X<Y, for example, Y=0.25) having the higher Al composition ratio is provided to the second layer 18 in the barrier layer 20. Accordingly, on the hetero semiconductor junction corresponding to the region other than the gate region, the concentration and mobility of the two-dimensional carrier gas induced therein can be increased.

Referring to specific examples, the embodiment of the present invention has been described above.

The present invention is not limited to the above-described embodiments by anyway. Various modifications can be implemented within a scope not departing from the subject matters of the present invention. For example, as shown in FIG. 7, a gate insulation film 30 may be provided between the bottom of the ditch 26 extending to the first layer 16 and the gate electrode 28 in the first embodiment to apply this element structure to an element of an MIS type gate structure. This modification can be applied to the other embodiment in the same manner. In this case, the leak current between the source and drain electrodes under the gate-off condition can further be suppressed. As the gate insulation film 30, a nitride film (for example, silicon nitride, aluminum nitride), oxide film (for example, silicon oxide, silicon dioxide, silicon oxinitride), a high relative permittivity (high-k) film, or a laminated film formed by combining these films in various manners can be used.

What is claimed is:

1. A semiconductor device comprising,
a channel layer including GaN,
a barrier layer formed on the channel layer, the barrier layer being formed by laminating a first layer including Al_{X}Ga_{1-X}N (0.05≦X≦0.25) and a second layer including Al_{Y}Ga_{1-Y}N (0.20≦Y≦0.28, X<Y) in order,
source and drain electrodes provided spaced apart from each other on the barrier layer, and
a gate electrode provided on the bottom of a ditch extending between the source and drain electrodes and formed with a depth starting from the top surface of the barrier layer reaching the first layer adjacent to the channel layer.

2. The semiconductor device of claim 1, wherein
the value X is increased in the direction toward the second layer side in the first layer.

3. The semiconductor device of claim 1, wherein,
the barrier layer is formed by repeating, a plurality of times, a cycle of laminating a film comprised of the first layer and the second layer, and
the number t of the repeated cycles is within a range of 3≦t≦10.

4. The semiconductor device of claim 1, wherein,
the barrier layer is formed by repeating, a plurality of times, a cycle of laminating a film comprised of the first layer and the second layer, and
the accumulated layer thickness of the barrier layer is 20 nm or more and 70 nm or less.

5. The semiconductor device of claim 1, further comprising a gate insulation film provided between the gate electrode and the bottom of the ditch reaching the first layer.

6. The semiconductor device of claim 5, wherein the gate insulation film comprises one of silicon nitride, aluminum nitride, silicon oxide, silicon dioxide, or multiple layers thereof.

7. The semiconductor device of claim 1, further comprising a substrate of sapphire, silicon carbide, or silicon, the substrate being adjacent to the channel layer, opposite the barrier layer.

8. The semiconductor device of claim 7, further comprising a buffer layer between the channel layer and the substrate.

9. The semiconductor device of claim 1, wherein the source electrode comprises aluminum.

10. The semiconductor device of claim 1, wherein the gate electrode comprises nickel.

11. A method of manufacturing a semiconductor device, comprising:
providing a channel layer including GaN;
forming barrier layer on the channel layer by laminating a first layer including Al_{X}Ga_{1-X}N (0.05≦X≦0.25) and a second layer including Al_{Y}Ga_{1-Y}N (0.20≦Y≦0.28, X<Y) in order;
forming a ditch in the barrier layer with a depth starting from the top surface of the barrier layer reaching the first layer adjacent to the channel layer;
forming a gate electrode in the ditch in the barrier layer.

12. The method of claim 11, wherein
the value X is increased in the direction toward the second layer side in the first layer.

13. The method of claim 11, further comprising forming a gate insulation film in the ditch prior to the formation of the gate electrode.

14. The method of claim 13, wherein the gate insulation film comprises one of silicon nitride, aluminum nitride, silicon oxide, silicon dioxide, or multiple layers thereof.

15. The method of claim 11, wherein the barrier layer is formed by repeating, a plurality of times, a cycle of laminating a film comprised of the first layer and the second layer, and
the number t of the repeated cycles is within a range of 3≦t≦10.

16. The method of claim 11, wherein the barrier layer is formed by repeating, a plurality of times, a cycle of laminating a film comprised of the first layer and the second layer, and
the accumulated layer thickness of the barrier layer is 20 nm or more and 70 nm or less.
